(19) United States
(12) Patent Application Publication
(10) Pub. No.: US 2013/0048861 A1
(43) Pub. Date: Feb. 28, 2013

(54) RADIATION DETECTOR, RADIATION DETECTOR FABRICATION METHOD, AND RADIOGRAPHIC IMAGE CAPTURE DEVICE

(71) Applicants: Yasunori OHTA, Kanagawa (JP); Keiichiro SATO, Kanagawa (JP); Naoyuki NISHINO, Kanagawa (JP); Haruyasu NAKATSUGAWA, Kanagawa (JP)

(72) Inventors: Yasunori OHTA, Kanagawa (JP); Keiichiro SATO, Kanagawa (JP); Naoyuki NISHINO, Kanagawa (JP); Haruyasu NAKATSUGAWA, Kanagawa (JP)

(73) Assignee: FUJIFILM CORPORATION, Tokyo (JP)

(21) Appl. No.: 13/558,316

(22) Filed: Jul. 25, 2012

(30) Foreign Application Priority Data
Aug. 26, 2011 (JP) 2011-185061

(51) Int. Cl. G01T 1/20; H01L 31/18; G01T 1/202

(52) U.S. Cl. 250/366; 438/29; 257/E31.129

(57) ABSTRACT

A radiation detector is provided that includes: plural pixels, each provided with a sensor portion including a switching element formed on a substrate and a photoelectric conversion element that is formed on the substrate and generates charge according to illuminated light; a planarizing layer formed on the plural pixels and including a light-blocking member with antistatic properties formed in a portion of the planarizing layer; and a light emitting layer that is formed on the planarizing layer and emits light according to irradiated radiation.

### CROSS-REFERENCE TO RELATED APPLICATION

This application claims priority under 35 USC 119 from Japanese Patent Application No. 2011-185061, filed on Aug. 26, 2011, the disclosure of which is incorporated by reference herein.

### BACKGROUND

1. Technical Field

The present invention relates to a radiation detector, a radiation detector fabrication method, and a radiographic image capture device.

2. Related Art

Radiographic image capture devices for capturing radiographic images are known in which a radiation detector detects radiation that has been irradiated from a radiation irradiation device and has passed through a subject. As the radiation detector for such a radiographic image capture device, detectors are known that are provided with a scintillator such as a fluorescent body that converts irradiated radiation into light, and a photoelectric conversion base configured from pixels. Each pixel is provided with a photoelectric conversion element that generates charge when illuminated with light converted by the scintillator, and a switching element that reads the charge generated in the photoelectric conversion element.

For example, technology is described in Japanese Patent Application Laid-Open (JP-A) No. 2010-3752 in which a photoelectric conversion device employed in a radiographic image capture device has a light barrier layer formed in regions between plural pixels, such that light receiving surfaces are exposed, in order to achieve a planarizing effect whilst also ensuring light barrier performance. In this technology, the light barrier layer is disposed on steps formed between photoelectric conversion elements and a substrate so as to achieve a flattened surface of the light barrier layer and light receiving surfaces of the photoelectric conversion elements.

A radiation detection device is described in JP-A No. 2000-131444 that is provided with plural pairs of photoelectric conversion elements and switching elements disposed on a sensor substrate, with a scintillator layer provided for converting incident radiation into light that is detectable by the photoelectric conversion elements. A planarizing layer that is a flat surface on the scintillator layer-contact face is provided between the sensor substrate and the scintillator layer.

In order to provide the scintillator on the photoelectric conversion base in such radiation detectors there is technology for raising the adhesion between the photoelectric conversion base and the scintillator.

For example, surface treatment such as plasma processing is generally performed to the surface of the photoelectric conversion base in order to raise adhesion. Technology is described for example in JP-A No. 2004-325442 for preventing fluorescent body layer delamination due to defective adhesion. In the technology atmospheric-pressure plasma processing is performed to the surface of a fluorescent body undercoat layer disposed on a sensor panel provided with photoelectric conversion elements, and then the fluorescent body layer is formed on the fluorescent body undercoat layer.

However, sometimes electrostatic damage of photoelectric conversion elements is triggered by static buildup on the surface of the photoelectric conversion base during surface treatment of the surface of the photoelectric conversion base. For example, the presence of air when plasma processing is performed at atmospheric pressure as surface treatment makes static buildup less likely to occur, and the risk of triggering electrostatic damage is accordingly low. However, there is a high risk of triggering electrostatic damage when plasma processing is performed in a vacuum.

Similar electrostatic damage is also sometimes triggered when static buildup occurs on the surface of the photoelectric conversion base, not only when performing surface treatment.

In order to prevent such electrostatic damage a conduction layer could conceivably be disposed between the scintillator and the photoelectric conversion base, however the thickness of the device would increase and there would be an increase the distance to the photoelectric conversion elements in such cases, making image blurring more likely to occur.

### SUMMARY

In order to address the above issues, an object of the present invention is to provide a radiation detector, a radiation detector fabrication method, and a radiographic image capture device that can prevent electrostatic damage of photoelectric conversion elements, and can also prevent images from becoming more susceptible to blurring.

In order to achieve the above object, a radiation detector of a first aspect of the present invention includes plural pixels, a planarizing layer and a light emitting layer. Each of the pixels is provided with a sensor portion including a switching element formed on a substrate and a photoelectric conversion element that is formed on the substrate and that generates charge according to illuminated light. The planarizing layer is formed on the plural pixels and includes a light-blocking member with antistatic properties formed in a portion of the planarizing layer. The light emitting layer is formed on the planarizing layer and emits light according to irradiated radiation.

A radiation detector fabrication method of a eleventh aspect of the present invention includes forming plural pixels on a substrate, each of the plural pixels provided with a sensor portion including a switching element and a photoelectric conversion element that generates charge according to illuminated light, forming a planarizing layer over the plural pixels with a light-blocking member with antistatic properties formed in a portion of the planarizing layer, and forming a light emitting layer on the planarizing layer, the light emitting layer emitting light according to irradiated radiation.

A radiographic image capture device of a twelfth aspect of the present invention includes the above radiation detector according to any one of the first to the tenth aspects and an image acquisition unit that acquires a radiographic image based on the charge amount of charges output from each of the plural pixels of the radiation detector.

### BRIEF DESCRIPTION OF THE DRAWINGS

Exemplary embodiments of the present invention will be described in detail based on the following figures, wherein:

FIG. 1 is a configuration diagram of a radiation detector;

FIG. 2 is a circuit diagram of a radiation detector;

FIG. 3 is a plan view illustrating a configuration of a radiation detector;

FIG. 4 is a cross-section of a radiation detector;

FIG. 5 is a cross-section of a radiation detector;

FIG. 6 is a plan view of a radiation detector;

FIG. 7 is a cross-section of a radiation detector;

FIG. 8 is a graph illustrating the light emission characteristics of CsI (Tl) and the absorption wavelength range of quinacridone;

FIG. 9 is a drawing illustrating a fabrication process of a radiation detector;

FIG. 10 is a drawing illustrating a fabrication process of a radiation detector;

FIG. 11 is a drawing illustrating a fabrication process of a radiation detector;

FIG. 12 is a schematic drawing figuratively illustrating a crystal configuration of a scintillator component of a radiation detector; and

FIG. 13 is a cross-section of a radiation detector according to a modified example.

### DETAILED DESCRIPTION

Explanation follows regarding examples of exemplary embodiments, with reference to the drawings.

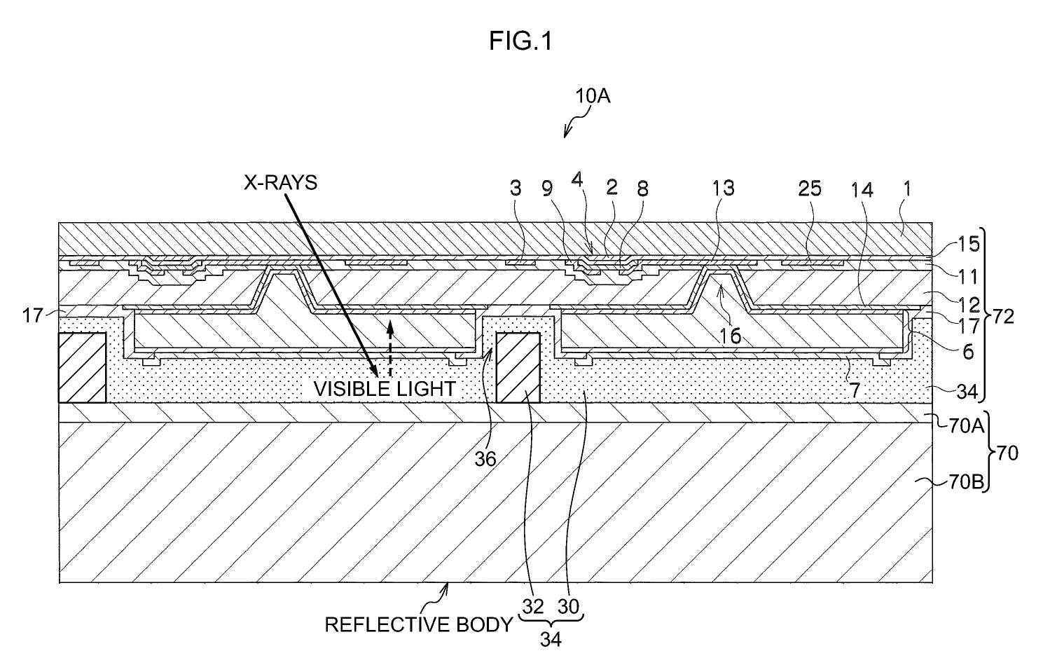

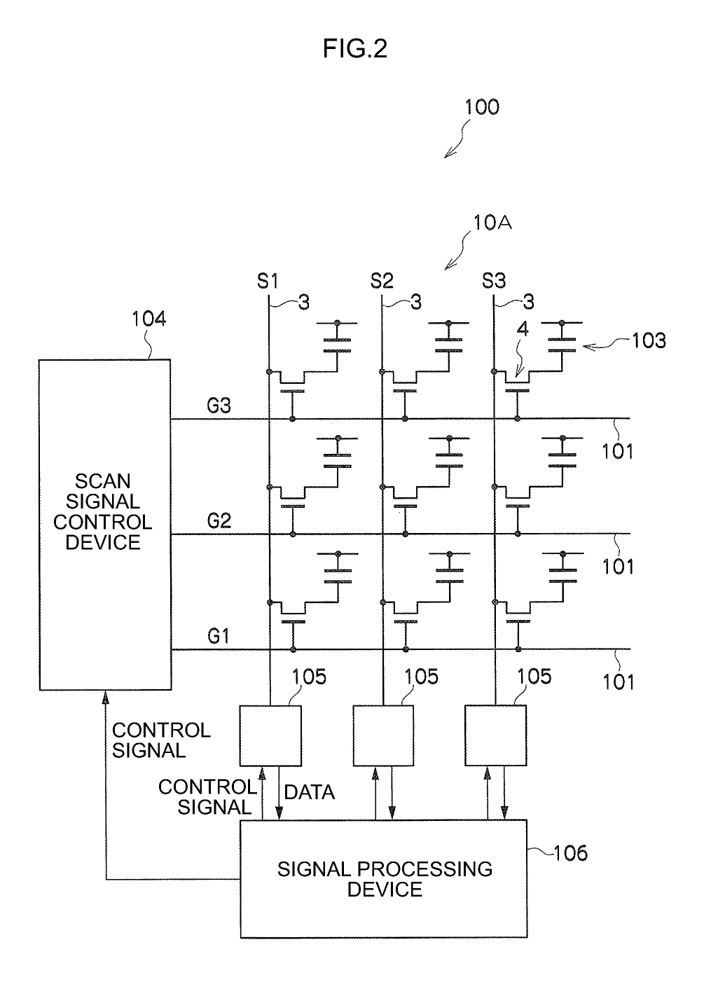

FIG. 1 and FIG. 2 illustrate the overall configuration of a radiographic image capture device 100 employing a radiation detector 10A according to a first exemplary embodiment. Note that a scintillator 70 has been omitted in FIG. 2.

The radiographic image capture device 100 of the present exemplary embodiment is equipped with the indirect conversion method radiation detector 10A.

The radiation detector 10A is provided with the scintillator 70 serving as a light emitting layer, and a photosensor-equipped TFT array substrate 72 serving as a photoelectric conversion base.

Explanation follows first regarding the scintillator 70. The scintillator 70 converts irradiated radiation into light and emits the converted light. A reflective body is provided at the bottom portion of the scintillator 70 illustrated in FIG. 1 to reflect light.

Explanation follows regarding the photosensor-equipped TFT array substrate 72.

The photosensor-equipped TFT array substrate 72 is provided with plural pixels disposed in a two-dimensional formation. Each of the pixels is configured including a sensor portion 103, provided with an upper electrode, a semiconductor layer and a lower electrode, described later, receiving light that has been converted by the scintillator 70 from irradiated radiation, and accumulating charge and a TFT switch 4 that reads charge accumulated in the sensor portion 103.

Plural scan lines 101 and plural signal lines 3 are disposed on the photosensor-equipped TFT array substrate 72 so as to intersect with each other. The scan lines 101 switch the TFT switches 4 ON or OFF. The signal lines 3 read charge accumulated in the sensor portions 103.

An electrical signal, corresponding to the amount of accumulated charge in the sensor portion 103, flows in each of the signal lines 3 by switching ON one or other of the TFT switches 4 connected to this signal line 3. A signal detection circuit 105 is connected to each of the signal lines 3 for detecting the electrical signal flowing out from each of the signal lines 3. A scan signal control device 104 is also connected to the scan lines 101 for outputting a scan signal to each of the scan lines 101 for ON/OFF switching of the TFT switches 4.

The signal detection circuit 105 is inbuilt with an amplifier circuit for each of the respective signal lines 3 for amplifying input electrical signals. Electrical signals input by each of the signal lines 3 are amplified by the amplifier circuits and detected in the signal detection circuit 105. The signal detection circuit 105 thereby detects the charge amount that has been accumulated in each of the sensor portions 103 as data for each pixel configuring a radiographic image.

A signal processing device 106 is connected to the signal detection circuit 105 and the scan signal control circuit 104. The signal processing device 106 executes specific processing on the electrical signals detected by the signal detection circuit 105. The signal processing device 106 also outputs a control signal expressing the timing of signal detection to the signal detection circuit 105, and outputs a control signal expressing the timing for scan signal output to the scan signal control device 104.

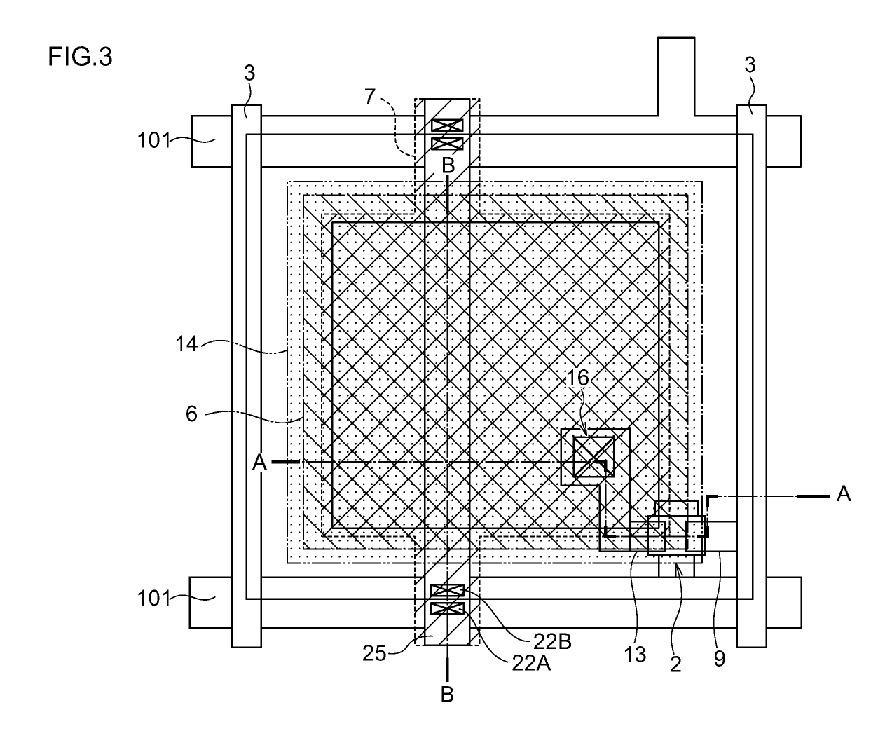

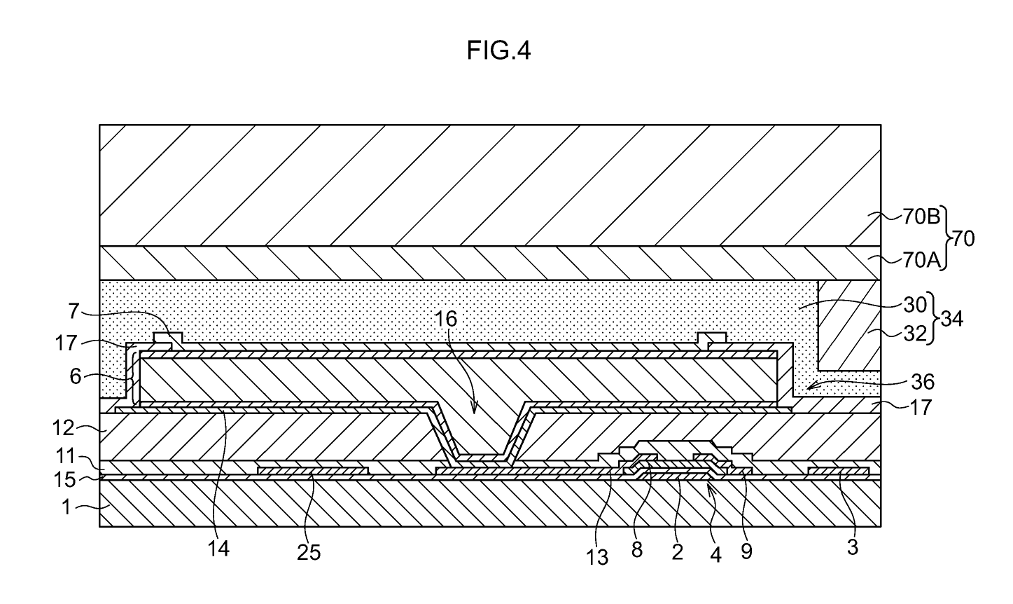

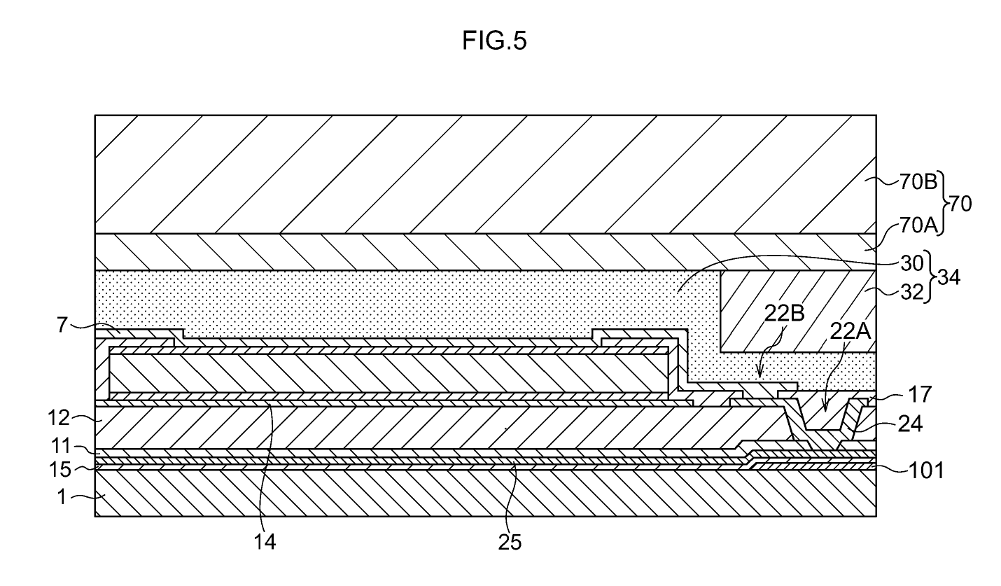

More detailed explanation now follows regarding the photosensor-equipped TFT array substrate 72 according to the present exemplary embodiment, with reference to FIG. 3 to FIG. 5. Note that FIG. 3 shows a plan view illustrating a structure of a single pixel unit on the photosensor-equipped TFT array substrate 72 according to the present exemplary embodiment. FIG. 4 shows a cross-section taken along the line A-A of FIG. 3. FIG. 5 shows a cross-section taken along the line B-B of FIG. 3. Note that FIG. 4 and FIG. 5 are top-bottom inverted relative to FIG. 1.

As shown in FIG. 4 and FIG. 5, the radiation detector 10A of the present exemplary embodiment is formed with an insulating substrate 1 configured from a material such as non-alkali glass, on which the scan lines 101 and gate electrodes 2 are formed. The scan lines 101 and the gate electrodes 2 are connected together (see FIG. 3). The wiring layer in which the scan lines 101 and the gate electrodes 2 are formed (this wiring layer is referred to below as the first signal wiring layer) is formed from Al and/or Cu, or a layered film mainly composed of Al and/or Cu. However, the material of the first signal wiring layer is not limited thereto.

An insulation film 15 is formed on the scan lines 101 and the gate electrodes 2 so as to cover one face of the scan lines 101 and the gate electrodes 2. The locations of the insulation film 15 positioned over the gate electrodes 2 are employed as a gate insulation film in the TFT switches 4. The insulation film 15 is, for example, formed from a material such as SiNₓ by, for example, Chemical Vapor Deposition (CVD) film forming.

A semiconductor active layer 8 is formed with an island shape on the insulation film 15 above each of the gate electrodes 2. The semiconductor active layer 8 is a channel portion of the TFT switch 4 and is, for example, formed from an amorphous silicon film.

Source electrodes 9 and drain electrodes 13 are formed in a layer above. The wiring layer in which the source electrodes 9 and the drain electrodes 13 are formed also has the signal lines 3 and common electrodes line 25 running parallel to the signal line 3 formed therein, as well as the source electrodes 9 and the drain electrodes 13. The source electrodes 9 are connected to the signal lines 3. The wiring layer in which the signal lines 3, the source electrodes 9 and the common electrode lines 25 are formed (this wiring layer is referred to below as the second signal wiring layer) is formed from Al and/or Cu, or a layered film mainly composed of Al and/or Cu. However, the material of the second signal wiring layer is not limited thereto.

A contact layer (not shown in the drawings) is formed between the semiconductor active layer 8 and both the source electrode 9 and the drain electrode 13. The contact layer is formed from an impurity doped semiconductor such as impurity doped amorphous silicon. Each of the TFT switches 4 is configured with such a configuration.

A TFT protection layer 11 is formed over substantially the whole surface (substantially all regions) where the pixels are provided on the substrate 1 so as to cover the semiconductor active layers 8, the source electrodes 9, the drain electrodes 13, the signal lines 3 and the common electrode lines 25. The TFT protection layer 11 is formed, for example, from a material such as SiNₓ by, for example, CVD film forming.

A coated intermediate insulation film 12 is formed on the TFT protection layer 11. The intermediate insulation film 12 is formed from a low permittivity (specific permittivity εᵣ=2 to 4) photosensitive organic material (examples of such materials include positive working photosensitive acrylic resin materials with a base polymer formed by copolymerizing methacrylic acid and glycidyl methacrylate, mixed with a naphthoquinone diazide positive working photosensitive agent) at a film thickness of 1 to 4 μm. In the radiation detector 10A according to the present exemplary embodiment, inter-metal capacitance between metal disposed in the layers above the intermediate insulation film 12 and below the intermediate insulation film 12 is suppressed to a small capacitance by the intermediate insulation film 12. Generally such materials also function as a planarizing film, exhibiting an effect of planarizing out steps in the layers below. A reduction in absorption efficiency and an increase in leak current due to unevenness of the semiconductor layer 6 can thereby be suppressed since the profile is flattened for the semiconductor layer 6 disposed above the intermediate insulation film 12. A contact hole 16 and a contact hole 22A are formed in the intermediate insulation film 12 and the TFT protection layer 11 at, respectively, positions facing each of the drain electrodes 13 and positions on the irradiated face side of the region where each of the scan lines 101 is formed.

A lower electrode 14 of each of the sensor portions 103 is formed on the intermediate insulation film 12 so as to cover the pixel region while also filling the contact hole 16. The lower electrode 14 is connected to the drain electrode 13 of the TFT switch 4. When the thickness of the semiconductor layer 6, described later, is about 1 μm there are substantially no limitations to the material of the lower electrode 14, as long as it is an electrically conductive material. The lower electrode 14 may therefore be formed using a conductive metal such as an aluminum material or indium tin oxide (ITO).

However, there is insufficient light absorption in the semiconductor layer 6 when the film thickness of the semiconductor layer 6 is thin (about 0.2 to 0.5 μm). An alloy or layered film with a main component of a light blocking metal is then preferably employed for the lower electrode 14 in order to prevent an increase in leak current occurring due to light illumination onto the TFT switch 4.

The semiconductor layer 6 is formed on the lower electrode 14 and functions as a photodiode. In the present exemplary embodiment, a photodiode of PIN structure is employed as the semiconductor layer 6, formed with stacked layers of an n⁺ layer, an i layer and a p⁺ layer stacked in sequence from the bottom. Note that each of the lower electrodes 14 is made larger than the respective semiconductor layer 6 in the present exemplary embodiment. When the thickness of the semiconductor layer 6 is thin (for example 0.5 μm or less) a light blocking metal is preferably additionally disposed so as to cover each of the TFT switches 4 in order to prevent light from being incident to the TFT switch 4.

A separation of 5 μm or greater is preferably secured between the edge portions of the lower electrodes 14 made from a light blocking metal and the channel portions of the TFT switches 4 in order to suppress light arising from light scattering and reflection within the device from being incident to the TFT switches 4.

A protection insulation film 17 is formed on the intermediate insulation film 12 and the semiconductor layer 6. The protection insulation film 17 is provided with an aperture at each portion where the semiconductor layers 6 are disposed. Upper electrodes 7 are formed on the semiconductor layer 6 and the protection insulation film 17 so as to at least cover each of the apertures in the protection insulation film 17. A material with high light-transparency such as ITO or Indium Zinc Oxide (IZO) is employed for example for the upper electrodes 7. Each of the upper electrodes 7 also functions as a conducting member for connection to the respective common electrode line 25 disposed in a lower layer for supplying a bias voltage to the upper electrode 7. As shown in FIG. 4 each of the common electrode lines 25 is connected through the contact hole 22A provided in the intermediate insulation film 12 to a contact pad 24 formed in the lower electrode 14 layer. Each of the upper electrodes 7 is also electrically connected to the respective common electrode line 25 due to the upper electrode 7 covering over a contact hole 22B provided in the protection insulation film 17.

Configuration may be made such that the upper electrode 7 and the conducting member for connecting the upper electrode 7 to the common electrode lines 25 are formed from metal in different layers to each other.

An insulation layer 30 and a planarizing layer 34 including light-blocking members 32 formed from a material with antistatic properties are formed on the semiconductor layer 6. The insulation layer 30 is, for example, formed from a similar material to the intermediate insulation film 12, however there is no limitation thereto.

Materials with antistatic properties refers to materials through which electricity does not readily pass but are, however, materials with a specific resistance at least capable of preventing static buildup. Generally there are progressively lower specific resistances in the sequence: insulating materials to antistatic materials to conducting materials. Conducting materials have lower specific resistance than antistatic materials and are materials through which electricity readily passes. They therefore can be regarded as materials with antistatic properties. The light-blocking members 32 may therefore be formed from a conducting material.

The radiation detector 10A is produced by forming each of the above layers on the substrate 1. As shown in FIG. 1 and FIG. 4, the stepped portions 36 occur across from the semiconductor layer 6 to the intermediate insulation film 12, namely between pixels.

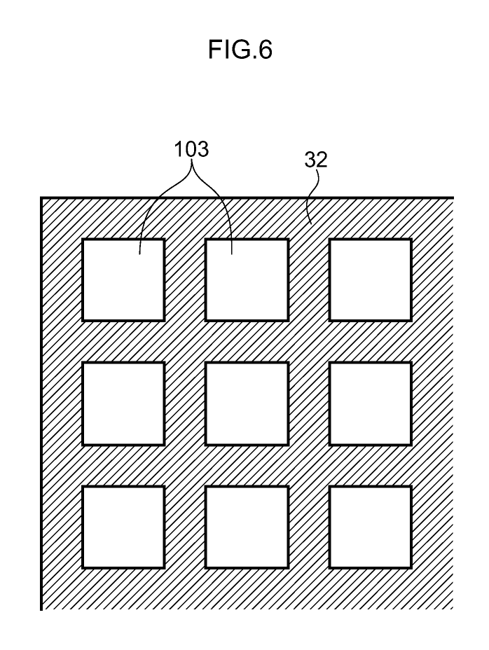

In the present exemplary embodiment the antistatic light-blocking members 32 are formed at the stepped portions 36. Namely, as shown in FIG. 6, the light-blocking members 32 are formed between the sensor portions 103 (between pixels). The light-blocking members 32 are formed for example from copper (Cu).

Inclined incident light from an adjacent pixel can thereby be prevented from being incident to a given pixel by forming the light-blocking members 32 between the pixels in this manner, and blurring of images can thereby be prevented. The light-blocking members 32 have antistatic properties. Consequently, even when the previously described surface treatment to improve adhesion is performed to the planarizing layer 34 prior to forming the scintillator 70 thereon, static buildup does not occur due to the presence of the antistatic light-blocking members 32, and electrostatic damage to the photodiodes can be prevented. The thickness of a radiation detector can be made thinner by providing the antistatic light-blocking members 32 at the stepped portions 36 rather than providing a separate independent antistatic layer on the planarizing layer 34, enabling the distance to be shortened for light travelling from the scintillator 70 to the photodiodes and enabling blurring of images to be suppressed from occurring.

The light-blocking members 32 may be configured by a member that does not block light of wavelengths over the whole of the visible spectrum, and may be configured by a member that absorbs a portion of the long wavelength components in the wavelengths of light emitted from the scintillator 70.

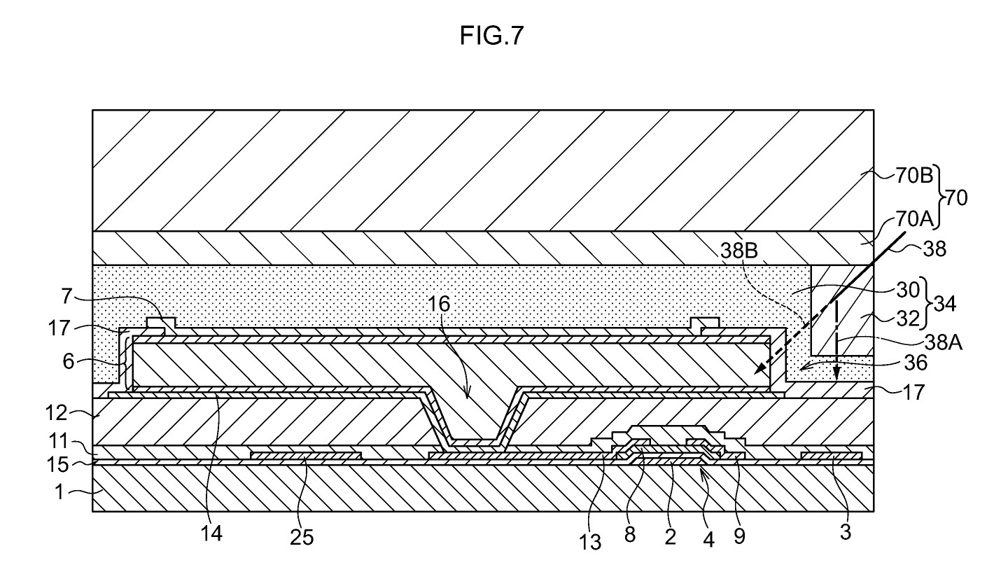

Long wavelength components of light are not generally so readily refracted as short wavelength components of light. Therefore, as shown in FIG. 7, short wavelength component light 38A present in inclined incident light 38 from an adjacent pixel is refracted and therefore not readily received by the photodiode of a given pixel. However, long wavelength components of light are not readily refracted, and so as shown in FIG. 7, long wavelength component light 38B present in inclined incident light 38 from an adjacent pixel is not readily refracted, and so is readily received by the photodiode in the given pixel, resulting in a tendency for image blurring to occur.

Therefore images can be prevented from more readily blurring as long as the light-blocking members 32 are members that absorb long wavelength component light in the emission wavelengths of the scintillator 70.

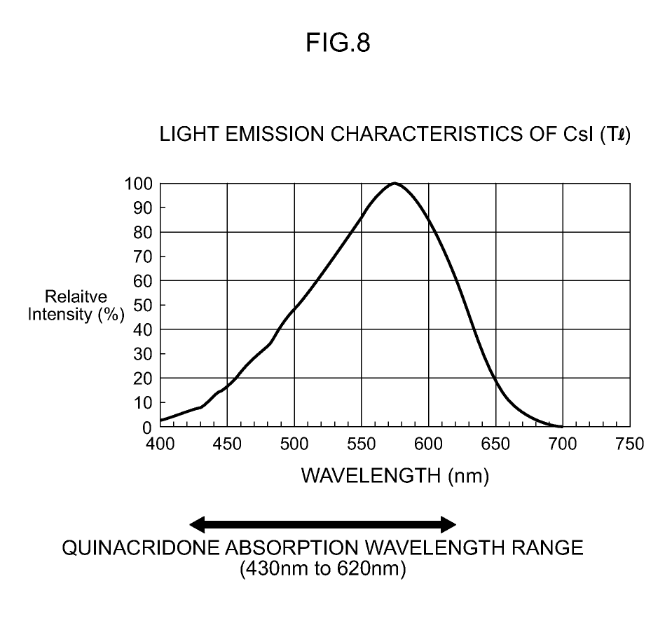

Consider, for example, a case in which the scintillator 70 is configured from CsI:Tl, and the photodiodes are configured from quinacridone. As shown in FIG. 8, the emission peak wavelength of CsI:Tl is 565 nm, however the emitted light includes light over a wide wavelength range (from 400 nm to 700 nm). However quinacridone has sensitivity to light in a wavelength range of 430 nm to 620 nm. In such a case inclined incident light can be cut out by configuring the light-blocking members 32 from a material that absorbs light of long wavelength components of 620 nm or longer, and image blurring can be prevented. When photodiodes are configured from quinacridone, even suppose a portion of inclined incident light of 620 nm or over was to pass through the light-blocking members 32, image blurring would not readily occur since the sensitivity of quinacridone to light of such wavelengths is low.

Examples of configurations for the light-blocking members 32 so as to absorb light of long wavelength components of 620 nm or greater include mixing a cyan colorant into a conducting material so as to absorb red light, namely light of wavelengths 620 nm to 750 nm. For example, when a conductive polymer is employed for the light-blocking members 32 then a colorant can be easily mixed in. Examples of cyan colorant that may be employed therefor include inorganic blue pigments such as ultramarine blue and Prussian blue (potassium ferric ferrocyanide). Examples of organic blue colorants that may be employed therefore include phthalocyanine, anthraquinone, indigoid and carbonium dyes. Pigments are present as particles in a resin, however there is no limitation to pigments and dyes dissolved in a resin may be employed.

Organic colorants are preferably employed when radiation is irradiated onto the photosensor-equipped TFT array substrate 72 side of the radiation detector 10 and a radiographic image is read by the photosensor-equipped TFT array substrate 72 provided on the radiation irradiation side, referred to as Irradiation Side Sampling (ISS). This is preferable in order for more X-rays to be allowed to reach the scintillator 70, since inorganic colorants more readily absorb radiation than inorganic colorants (due to containing elements with larger atomic numbers).

Note that it is preferable to absorb even a little red light. However, since there is a higher possibility of inclined incident light being received by adjacent pixels when the size of the pixels is small (for example 100 μm or less), preferably more colorant is employed in such cases to raise the absorptance of red light.

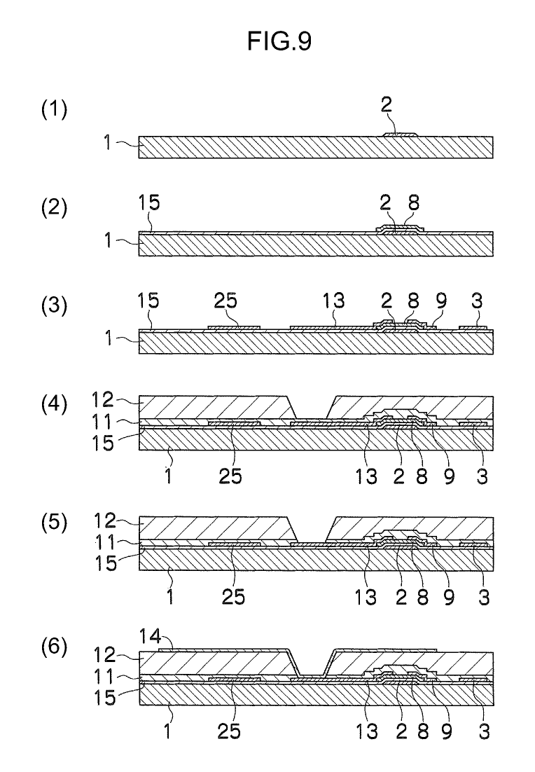

Explanation follows regarding an example of fabrication processes of the radiation detector 10A according to the present exemplary embodiment, with reference to FIG. 9 to FIG. 11.

First, the gate electrodes 2 and the scan lines 101 are formed as the first signal wiring layer on the substrate 1 (see FIG. 9 (1)). The first signal wiring layer is formed from a low resistance metal such as Al or an Al alloy, or formed from a stacked film of barrier metal layers formed from a high melting point metal, deposited on the substrate 1 using a sputtering method to a film thickness of about 100 nm to 300 nm. Patterning of a resist film is then performed using photolithographic technology. The metal film is then patterned using a wet etching method or a dry etching method with an Al etchant. The first signal wiring layer is completed by removing the resist.

The insulation film 15, the semiconductor active layer 8 and a contact layer (not shown in the drawings) are then deposited in sequence on the first signal wiring layer (FIG. 9 (2)). The insulation film 15 is formed from SiNx with a film thickness of 200 nm to 600 nm, the semiconductor active layer 8 is formed from amorphous silicon with a film thickness of about 20 nm to 200 nm, and the contact layer is formed from impurity doped amorphous silicon with a film thickness of about 10 nm to 100 nm by deposition using a Plasma-Chemical Vapor Deposition (P-CVD) method. Then, similarly to with the first signal wiring layer, patterning of a resist is performed using photolithographic technology. The semiconductor active regions are then formed by selectively dry etching the semiconductor active layer 8 and the contact layer formed from an impurity doped semiconductor down to the insulation film 15.

The signal lines 3, the source electrodes 9, the drain electrodes 13, and the common electrode lines 25 are then formed as the second signal wiring layer as a layer above the insulation film 15 and the semiconductor active layer 8 (FIG. 9 (3)). The second signal wiring layer is, similarly to the first signal wiring layer, formed with a film thickness of about 100 nm to 300 nm from a low resistance metal such as Al or an Al alloy, formed from a stacked film of barrier metal layers formed from a high melting point metal, or formed from a single layer of high melting point metal such as Mo. Similarly to with the first signal wiring layer, patterning is performed using photolithographic technology, then the metal film is patterned using a wet etching method or a dry etching method with an Al etchant. The insulation film 15 is not removed when this is performed due to employing a selective etching method. The contact layer and a portion of the semiconductor active layer 8 are then removed by further dry etching to form a channel region.

The TFT protection layer 11 and the intermediate insulation film 12 are then formed in sequence above the layers formed as described above (FIG. 9 (4)). There are cases in which the TFT protection layer 11 and the intermediate insulation film 12 are formed as a single inorganic material body, cases in which they are formed as stacked layers of a protection-insulation film formed from an inorganic material and an intermediate insulation film formed from an organic material, and cases in which they are formed as a single layer intermediate insulation film formed from an organic material. In the present exemplary embodiment, in order to suppress the capacitance between the lower layer common electrode lines 25 and the lower electrodes 14 and stabilize the characteristics of the TFT switches 4 a stacked layer structure is adopted of a photosensitive intermediate insulation film 12 and the TFT protection layer 11 formed from an inorganic material. Such a structure may be achieved by for example forming the TFT protection layer 11 using CVD film forming, and coating a material for the photosensitive intermediate insulation film 12 as a coating material thereon. Then after pre-baking, and after passing through exposure and developing steps, the layers are then formed by firing.

The TFT protection layer 11 is then patterned by photolithographic technology (FIG. 9 (5)). Note that this step is not required when there is no TFT protection layer 11 disposed.

A sputtering method is then employed to deposit a metal material such as an aluminum material or ITO onto the top layer of the layers described above. The film thickness is about 20 nm to 200 nm. The lower electrodes 14 are formed by performing patterning with photolithographic technology, and patterning with a wet etching method or a dry etching method using for example a metal etchant (FIG. 9 (6)).

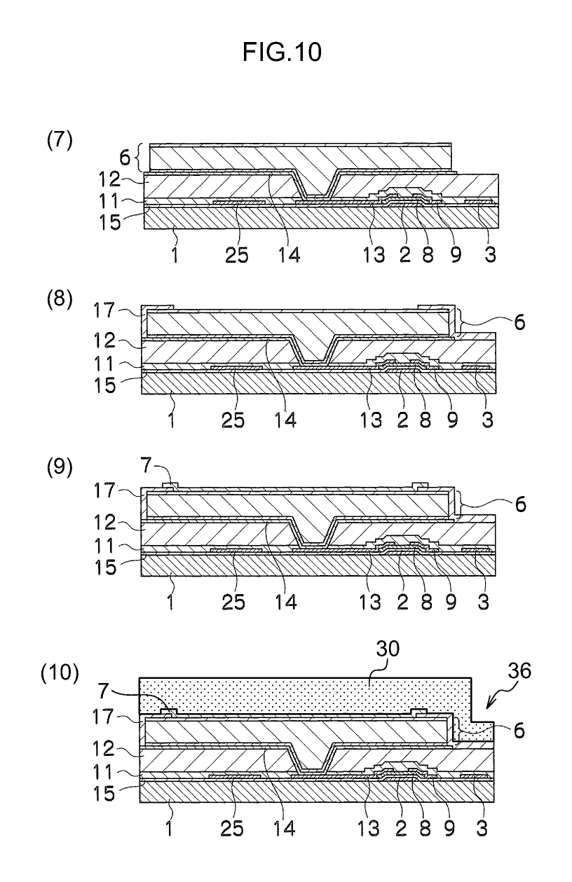

The semiconductor layer 6 is then formed by using a CVD method to deposit each layer of an n+, an i, and a p+ layer, in sequence from the bottom layer (FIG. 10 (7)). The respective film thicknesses are n+ layer 50 nm to 500 nm, i layer 0.2 μm to 2 μm, p+ layer 50 nm to 500 nm. Each layer of the semiconductor layer 6 is deposited in sequence and patterned with photolithographic technology. The semiconductor layer 6 is then completed by selectively etching down to the intermediate insulation film 12 below using dry etching or wet etching.

Note that configuration may be made as a PIN diode by depositing layers in the sequence p+, i, n+ instead of depositing layers in the sequence n+, i, p+.

The SiNx protection insulation film 17 is then deposited using for example a CVD method so as to cover the semiconductor layer 6. The film thickness is about 100 nm to 300 nm. Patterning is then performed with photolithographic technology, and patterning with dry etching is performed to form apertures (FIG. 10 (8)). While an example has been given here in which the protection insulation film 17 is formed from SiNx using CVD film forming there is no limitation to SiNx and any insulating material may be employed.

The connection locations of the upper electrodes 7 and the common electrode lines 25 are then formed (FIG. 10 (9)). The connection locations of the upper electrodes 7 and the common electrode lines 25 are formed above the layers that have been formed as described above by depositing a transparent conductive material such as ITO using a sputtering method. The film thickness is about 20 nm to 200 nm. Patterning is performed using photolithographic technology and using a wet etching method or a dry etching method with an ITO etchant to pattern the upper electrodes 7. The protection insulation film 17 below is not damaged due to selectively etching during this process.

The insulation layer 30 is then formed so as to cover the protection insulation film 17 and the upper electrode 7 (FIG. 10 (10)). The stepped portions 36 occur at this stage due to the steps between the semiconductor layers 6 and the intermediate insulation film 12.

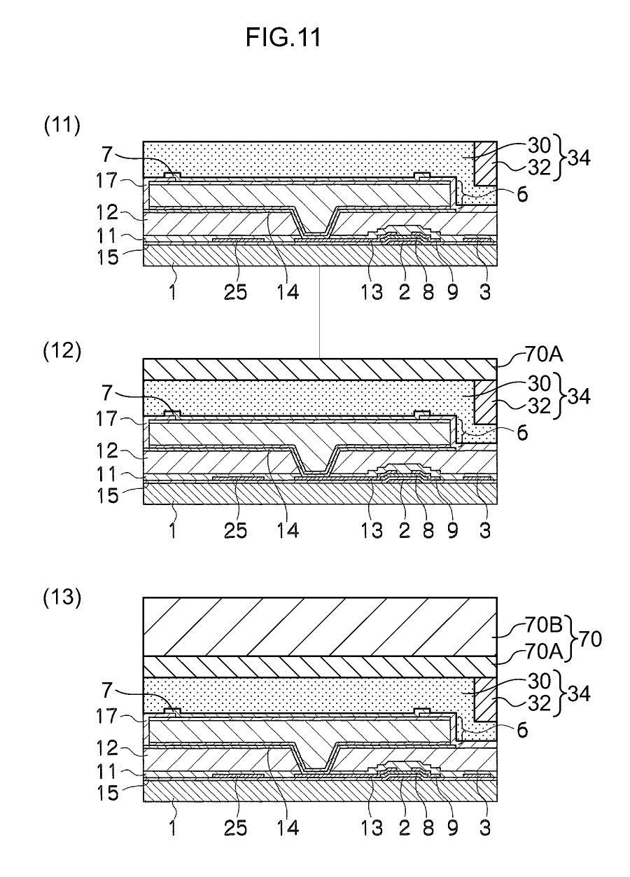

The light-blocking members 32 are then formed on the stepped portions 36 (FIG. 11 (11)). The planarizing layer 34 is accordingly formed.

Non-columnar crystals 70A are then directly vapor deposited on the planarizing layer 34 (FIG. 11 (12)). Alkali halide non-columnar crystals such as CsI:Tl may be employed here as the non-columnar crystals.

Columnar crystals 70B are then grown on the non-columnar crystals 70A (FIG. 11 (13)). Similarly to with the non-columnar crystals 70A, alkali halide columnar crystals such as CsI:Tl may also be employed here as the columnar crystals 70B.

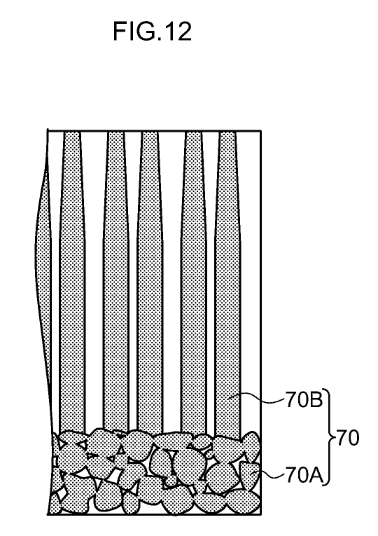

FIG. 12 is a schematic diagram illustrating a crystalline region in the scintillator 70. As shown in FIG. 12, the non-columnar crystals 70A are irregular joined and overlapping crystals with defined gaps hardly discernible between the crystals. However, the columnar crystals 70B exhibit substantially uniform cross-section along the crystal growth direction, with independent column shape portions having gaps present at the peripheral portions thereof. This region is a region of the scintillator 70 with high efficiency of light emission, and the gaps between the columnar crystals also act as light guides to suppress light diffusion.

Such a scintillator 70 configured with the contiguous non-columnar crystals 70A and columnar crystals 70B can be formed by employing for example a vapor deposition method on the planarizing layer 34. An explanation follows of an example in which CsI:Tl is employed as the scintillator 70.

A usual vapor deposition method may be employed. Namely, CsI:Tl may be heated and vaporized by passing current through a resistance pot furnace in a vacuum of 0.01 Pa to 10 Pa, and CsI:Tl deposited on the planarizing layer 34 held at a temperature between room temperature (20° C.) and 300° C.

When forming a crystal phase of CsI:Tl on the planarizing layer 34 with a vapor deposition method, an aggregation of crystals is first formed from comparatively small-sized, irregular shaped or substantially spherical, crystals. During execution of the vapor deposition method, columnar crystals can be grown by continuing the vapor deposition method after the non-columnar crystal region has been formed, but with a change made to at least one condition out of the degree of vacuum or the temperature of the support body.

Namely, after the non-columnar crystal region has been formed to a specific thickness, it is possible to efficiently grow uniform columnar crystals by adopting at least one measure out of raising the degree of vacuum and/or raising the temperature of the planarizing layer 34.

The radiation detector 10A is thereby obtained with the scintillator 70 formed by direct vapor deposition on the planarizing layer 34.

Note that prior to forming the scintillator 70 on the planarizing layer 34 surface treatment such as plasma processing may be performed to raise adhesion, as described above. In such cases electrostatic damage to the photodiodes can be prevented due to the antistatic light-blocking members 32 being formed in the planarizing layer 34.

Due to the configuration with the antistatic light-blocking members 32 formed in the portion of the planarizing layer 34, the thickness of the radiation detector can also be made thinner than in cases where an independent antistatic layer is provided between the planarizing layer 34 and the scintillator 70. Image blurring can also be prevented since the distance from the scintillator 70 to the photodiodes can be shortened.

Explanation follows regarding operation principles of the radiation detector 10A configured as described above.

When X-rays are irradiated from above in FIG. 1, the irradiated X-rays are absorbed in the scintillator 70 and converted into visible light. Note that X-rays may also be irradiated from below in FIG. 1, and the irradiated X-rays are also absorbed in the scintillator 70 and converted into visible light in such cases. The light intensity emitted from the scintillator 70 is about 0.5 to 2 μW/cm² for normal medical diagnostic X-ray imaging. The emitted light passes through the insulation layer 30 and is irradiated onto the semiconductor layer 6 in each of the sensor portions 103 that are disposed in the array on the photosensor-equipped TFT array substrate 72.

In the radiation detector 10A the semiconductor layer 6 is provided so as to be separated into individual pixel units. Each of the individual semiconductor layers 6 is applied with a specific bias voltage from the respective upper electrode 7 through the common electrode line 25, and charge is generated inside the semiconductor layer 6 when light is illuminated thereon. For example, a negative bias voltage is applied to the upper electrode 7 for a PIN structure formed with stacked layers n⁺-i-p⁺ (n⁺ amorphous silicon, amorphous silicon, p⁺ amorphous silicon) stacked in sequence from the bottom. When the film thickness of the i layer is about 1 μm, the bias voltage applied is about −10V to −5V. A current of only several to several tens of pA/mm² or less flows in the semiconductor layer 6 under such conditions when not illuminated. However, a light current of about 0.3 μA/mm² is generated in the semiconductor layer 6 when light is illuminated (at 100 μW/cm²) under such conditions. The generated charge is collected in the lower electrodes 14. The lower electrodes 14 are connected to the drain electrodes 13 of the TFT switches 4 and the source electrodes 9 of the TFT switches 4 are connected to the signal lines 3. During image detection a negative bias is applied to the gate electrodes 2 of the TFT switches 4 to maintain an OFF state such that the charge collected by the lower electrodes 14 is accumulated.

During image reading, an ON signal (+10 to +20V) is applied through the scan lines 101 in sequence to the gate electrodes 2 of the TFT switches 4. The TFT switches 4 are thereby switched ON in sequence, and electrical signals according to the charge amount that has been accumulated in the lower electrodes 14 flow out in the signal lines 3. The signal detection circuit 105 thereby detects the amount of charge that has accumulated in each of the sensor portions 103 based on the electrical signals flowing out through the signal lines 3 as data for each of the pixels configuring an image. Image data can thereby be obtained for an image expressing the X-rays irradiated onto the radiation detector 10A.

The radiation detector 10A according to the present exemplary embodiment is configured with the antistatic light-blocking members 32 formed in a portion of the planarizing layer 34. The radiation detector 10A is hence able to prevent electrostatic damage to photodiodes even when surface treatment such as plasma processing is performed to raise adhesion prior to forming the scintillator 70 on the planarizing layer 34.

Due to the configuration with the antistatic light-blocking members 32 formed in a portion of the planarizing layer 34, the thickness of a radiation detector can also be made thinner than in cases in which a separate independent antistatic layer is provided between the planarizing layer 34 and the scintillator 70. Image blurring can also be prevented due to being able to shorten the distance from the scintillator 70 to the photodiodes.

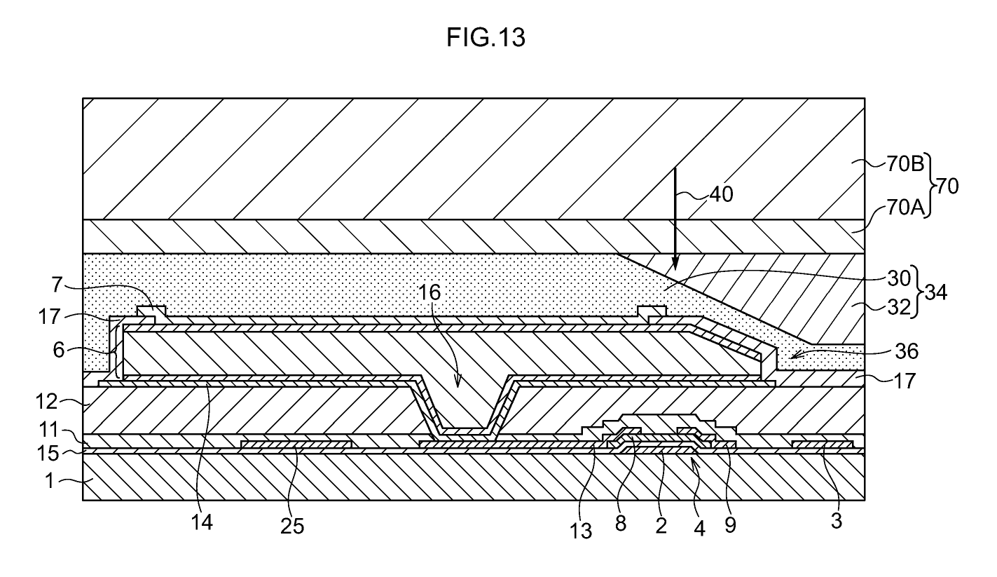

Configuration may be made, as shown in FIG. 13, with the semiconductor layer 6, namely the photodiode edge portions 6A formed with a tapered profile. In such cases, due to the insulation layer 30 being formed to correspond to the tapered profile of the edge portions 6A, the light-blocking members 32 can also be formed directly above the TFT switches 4. Light 40 from the scintillator 70 is thereby absorbed by the light-blocking members 32, enabling suppression of switching noise emission arising from light being illuminated onto the TFT switches 4 formed from a material such as amorphous silicon.

Note that while explanation has been given in the present exemplary embodiment of a case in which the scintillator 70 is formed from CsI:Tl the scintillator 70 is not limited to being formed from this material. For example, other crystals such as crystals of GOS (Gd₂O₂S:Tb), NaI:Tl (Thallium activated sodium iodide) and CsI:Na (sodium activated cesium iodide) may be employed in the scintillator 70. The scintillator 70 is, however, not limited to a scintillator formed from one of these materials.

While in the present exemplary embodiment explanation has been given of an example in which the scintillator 70 is directly vapor deposited on the planarizing layer 34 there is no limitation thereto. For example, a separately formed scintillator 70 may be laminated to the planarizing layer 34 through an adhesive layer (bonding layer).

In the present exemplary embodiment a case has been explained in which radiation is irradiated onto the photosensor-equipped TFT array substrate 72 side and light that has been converted by the scintillator 70 and reflected is detected by the photodiodes of the photosensor-equipped TFT array substrate 72 to be read as a radiographic image, employing what is referred to as Irradiation Side Sampling (ISS). There is however no limitation thereto and a similar advantageous effect is achieved when radiation is irradiated from the scintillator 70 side, and light that has been converted by the scintillator 70 is detected by the photodiodes of the photosensor-equipped TFT array substrate 72 so as to read a radiographic image, in what is referred to as Penetration Side Sampling (PSS).

Configuration may also be made with an organic CMOS sensor formed from a material containing an organic photoelectric conversion material employed for the sensor portions 103 of the radiation detector 10A. Configuration may also be made with an organic TFT array-sheet of organic transistors containing an organic material arrayed as thin film transistors on a flexible sheet employed as the photosensor-equipped TFT array substrate 72 of the radiation detector 10A. An example of such an organic CMOS sensor is described in JP-A No. 2009-212377. An example of such an organic TFT array-sheet is described in the Nikkei Newspaper article published online (search date May 8, 2011) “Tokyo University develops “Ultra-flexible Organic Transistor””, Internet <URL: http://www.nikkei.com/tech/trend/article/g=96958A9C93819499E2EAE2E0E48DE2EAE3E3E0E2E3E2E2E2E2E2E2E2;p=9694E0E7E2E6E0E2E3E2E2E0E2E0>.

As a result of the advantages of being able to perform high speed photoelectric conversion and making the substrate thinner when a CMOS sensor is employed as the sensor portions 103 of the radiation detector 10A, radiation absorption can be suppressed in ISS applications and there is the advantage of particular suitability in application to mammographic imaging.

The photosensor-equipped TFT array substrate 72 may be configured with a flexible substrate. An ultra-thin plate glass base produced by recently developed float technology is suitably applied as a substrate for such a flexible substrate due to being able to raise the transmissivity to radiation. Examples of ultra-thin plate glass bases that may be applied in such cases include, for example, bases described in the announcement published online, online search Aug. 20, 2011 “Asahi Glass Company (AGC) Develops Worlds Thinnest Sheet Float Glass at Just 0.1 MM”, Internet <URL: http://www.agc.com/news/2011/0516.pdf”.

Note that while the present invention has been explained above by way of exemplary embodiments the technical scope of the present invention is not limited by the scope of the exemplary embodiments described above. Various modifications and improvements may be made to the above exemplary embodiments within a scope not departing from the spirit of the present invention, and such modifications and improvements are contained within the technical scope of the present invention.

The above exemplary embodiments do not limit the invention as recited in the claims, and not all of the features explained in the above exemplary embodiments are required to be combined to realize the solution of the invention. The above exemplary embodiments include various aspects of invention, and various aspects of the invention can be obtained by suitably combining plural of the configuration elements described. As long as an advantageous effect can be obtained even when a number of the configuration elements are omitted from the total configuration elements described in the exemplary embodiments then any such configuration with omitted configuration elements can also be obtained as an aspect of the invention.

The radiation detector according to the present exemplary embodiment is not only applicable to a portable radiographic image capture device as configured by an electronic cassette, and application may also be made to a fixed radiographic image capture device.

While explanation has been given of an example in which the present invention is applied to a radiographic image capture device for capturing radiographic images by detecting X-rays as the radiation in the above exemplary embodiments the present invention is not limited thereto. The radiation to be detected may, for example, be X-rays, visible light, ultraviolet radiation, infrared radiation, gamma radiation or a particle beam.

The configuration of the radiation detector 10A explained in the above exemplary embodiments is merely an example, and obviously various modifications are possible with a scope not departing from the spirit of the present invention.

According to the radiation detector of a first aspect of the present invention, configuration is made with the planarizing layer formed on the plural pixels and the antistatic light-blocking members formed in the portion of the planarizing layer. Electrostatic damage to the photoelectric conversion elements can accordingly be prevented even when surface treatment is performed to raise adhesion when forming the light emitting layer on the planarizing layer, since charge does not result in static buildup due to provision of the antistatic light-blocking members. Inclined incident light from adjacent pixels can also be cut-off from being incident to a given pixel, thereby preventing images from becoming more susceptible to blurring.

According to a second aspect of the present invention, in a first aspect, that the light-blocking member may be formed between the plural pixels.

According to a third aspect of the present invention, in the first or the second aspect, the light emitting layer may be formed by crystals that emit light according to irradiated radiation directly vapor deposited on the planarizing layer.

According to a fourth aspect of the present invention, in the third aspect, the light emitting layer is formed by non-columnar crystals that emit light according to irradiated radiation directly vapor deposited on the planarizing layer and columnar crystals formed on the non-columnar crystals.

According to a fifth aspect of the present invention, in any one of the first to the fourth aspects, an edge portion of the photoelectric conversion element is formed with a tapered profile and the switching element is formed on the edge portion side of the photoelectric conversion element.

According to a sixth aspect of the present invention, in any one of the first to the fifth aspects, the light-blocking member absorbs a portion of the long wavelength components of light emitted by the light emitting layer.

According to a seventh aspect of the present invention, in the sixth aspect, the light-blocking member includes an organic colorant.

According to a eighth aspect of the present invention, in the sixth or the seventh aspect, the photoelectric conversion element includes quinacridone.

According to an eighth aspect of the present invention, in any one of the first to the eighth aspects, the light emitting layer includes CsI.

According to a second aspect of the present invention, in any one of the first to the ninth aspects, the radiation detector may also be employed for Irradiation Side Sampling (ISS) in which radiation is irradiated onto the substrate side of the radiation detector to acquire a radiographic image.

A radiographic image capture device of the present invention has the advantageous effect of being able to prevent electrostatic damage to the photoelectric conversion elements and being able to prevent images from becoming more susceptible to blurring.

What is claimed is:

1. A radiation detector comprising:
a plurality of pixels, each provided with a sensor portion comprising a switching element formed on a substrate and a photoelectric conversion element that is formed on the substrate and that generates charge according to illuminated light;
a planarizing layer formed on the plurality of pixels and comprising a light-blocking member, having antistatic properties, formed in a portion of the planarizing layer; and
a light emitting layer that is formed on the planarizing layer and emits light according to irradiated radiation.

2. The radiation detector of claim 1, wherein the light-blocking member is formed between the plurality of pixels.

3. The radiation detector of claim 2, wherein the light-blocking member is formed in a region, of the planarizing layer, opposing a stepped portion formed between the plurality of pixels.

4. The radiation detector of claim 1, wherein the light emitting layer is formed by crystals that emit light according to irradiated radiation directly vapor deposited on the planarizing layer.

5. The radiation detector of claim 4, wherein the light emitting layer is formed by non-columnar crystals, that emit light according to irradiated radiation, directly vapor deposited on the planarizing layer and by columnar crystals formed on the non-columnar crystals.

6. The radiation detector of claim 1, wherein an edge portion of the photoelectric conversion element is formed with a tapered profile and the switching element is formed on the edge portion side of the photoelectric conversion element.

7. The radiation detector of claim 2, wherein an edge portion of the photoelectric conversion element is formed with a tapered profile and the switching element is formed on the edge portion side of the photoelectric conversion element.

8. The radiation detector of claim 4, wherein an edge portion of the photoelectric conversion element is formed with a tapered profile and the switching element is formed on the edge portion side of the photoelectric conversion element.

9. The radiation detector of claim 1, wherein the light-blocking member absorbs a portion of long wavelength components of light emitted by the light emitting layer.

10. The radiation detector of claim 2, wherein the light-blocking member absorbs a portion of long wavelength components of light emitted by the light emitting layer.

11. The radiation detector of claim 6, wherein the light-blocking member absorbs a portion of long wavelength components of light emitted by the light emitting layer.

12. The radiation detector of claim 9, wherein the light-blocking member comprises an organic colorant.

13. The radiation detector of claim 9, wherein the photoelectric conversion element comprises quinacridone.

14. The radiation detector of claim 1, wherein the light emitting layer comprises CsI.

15. The radiation detector of claim 1, wherein the radiation detector is employed for Irradiation Side Sampling in which radiation is irradiated onto the substrate side of the radiation detector to acquire a radiographic image.

16. A radiation detector fabrication method comprising:
forming a plurality of pixels on a substrate, each of the plurality of pixels comprising a sensor portion including a switching element and a photoelectric conversion element that generates charge according to illuminated light;
forming a planarizing layer over the plurality of pixels with a light-blocking member, having antistatic properties, formed in a portion of the planarizing layer; and
forming a light emitting layer on the planarizing layer, the light emitting layer emitting light according to irradiated radiation.

17. A radiographic image capture device comprising:
the radiation detector of claim 1; and
an image acquisition unit that acquires a radiographic image based on a charge amount of charge output from each of the plurality of pixels of the radiation detector.

18. A radiographic image capture device comprising:
the radiation detector of claim 2; and
an image acquisition unit that acquires a radiographic image based on a charge amount of charge output from each of the plurality of pixels of the radiation detector.

19. A radiographic image capture device comprising:
the radiation detector of claim 6; and
an image acquisition unit that acquires a radiographic image based on a charge amount of charge output from each of the plurality of pixels of the radiation detector.

20. A radiographic image capture device comprising:
the radiation detector of claim 9; and
an image acquisition unit that acquires a radiographic image based on a charge amount of charge output from each of the plurality of pixels of the radiation detector.
